(19) United States
(12) Patent Application Publication
(10) Pub. No.: US 2007/0248127 A1
(43) Pub. Date: Oct. 25, 2007

(54) Optical-element-cooling devices and exposure apparatus comprising optical elements including same

(75) Inventor: Masayuki Shiraishi, Kumagaya-shi (JP)

Correspondence Address: KLARQUIST SPARKMAN, LLP, 121 SW SALMON STREET, SUITE 1600, PORTLAND, OR, 97204, US

(73) Assignee: Nikon Corporation

(21) Appl. No.: 11/711,958

(22) Filed: Feb. 27, 2007

(30) Foreign Application Priority Data
Apr. 24, 2006 (JP) JP2006-119620

(51) Int. Cl. H01S 3/04; H01L 21/3115

(52) U.S. Cl. 372/36; 438/694

(57) ABSTRACT

Cooling devices are disclosed for use with mirrors and other optical elements subject to heating during use, especially as used in lithographic exposure apparatus. The cooling devices pose minimal risk of damage caused by coolant leaks, provide simplified maintenance, and reduce vibrations while providing good cooling performance. An exemplary cooling device includes a cooling element (e.g., Peltier element) proximal to the optical element and a heat-conduction member mounted on the heat-dissipating side of the cooling element. The heat-conduction member extends, within the exposure apparatus, away from the optical element, and the extended portion of the heat-conduction member is cooled.

### FIELD

This disclosure relates to devices used for cooling a reflective mirror or other optical element in an optical system of an exposure apparatus. This disclosure also pertains to exposure apparatus comprising at least one such cooling device. In particular, this disclosure relates to optical-element-cooling devices that minimize potential damage caused by liquid leaks from coolant conduits and that minimize adverse effects on the optical system caused by vibration of coolant conduits, while maintaining cooling performance.

### BACKGROUND

In certain types of lithographic exposure apparatus, cooling devices are used for cooling reflective mirrors and other optical elements of the apparatus. Summarized below is an example of a conventional lithographic exposure apparatus that uses extreme-ultraviolet (EUV) light as an exposure light. The apparatus is shown in FIG. 7, and comprises an EUV light source 201 that produces a beam 200 of EUV light. An illumination-optical system 203 irradiates the beam 200 onto a reticle 202 mounted on a reticle stage 206. EUV light 200 reflected from the reticle 202 is patterned by the circuit pattern defined by the reticle. A projection-optical system 205 projects a reduced image of the circuit pattern onto a wafer 204 that is mounted on a wafer stage 207. Thus, the EUV light 200 passing through the projection-optical system 205 imprints (“transfers”) the circuit pattern onto the wafer 204.

FIG. 6 shows an exemplary configuration of a conventional projection-optical system 205 for use with EUV light. The projection-optical system 205 is situated between the reticle 202 and the wafer 204. The projection-optical system 205 comprises, for example, six reflective mirrors M1-M6. EUV light reflected from the reticle 202 is reflected in succession by the six reflective mirrors M1-M6 to reach the wafer 204. The reflective mirrors M1-M6 are held and positioned by lens barrels within lens barrels (not shown). Each reflective mirror M1-M6 reflects a substantial portion of respective incident EUV light; however, a portion of the incident light is absorbed by the mirror. Light energy absorbed by a reflective mirror usually accumulates in the mirror as heat. Hence, with continued EUV irradiation of the mirror, the temperature of the mirror increases. A significant temperature rise can cause an unacceptable degree of thermal deformation of the mirror, which can adversely affect the optical characteristics of the mirror. Hence, at least some of the reflective mirrors must be cooled.

A projection-optical system used in an EUV exposure apparatus is contained in a chamber maintained at high vacuum. The residual gas in the chamber is a non-atmospheric gas. Consequently, since the reflective mirrors of the system cannot be cooled by circulation of atmospheric gas in the chamber, it is especially important that the mirrors be cooled. In the projection-optical system of FIG. 7 summarized above, each of the reflective mirrors M1-M6 comprises a respective cooling device C1-C6 situated and configured to cool the respective mirror. In this regard, see Japan Laid-Open Patent Document No. 2004-29314, incorporated herein by reference.

A conventional mirror-cooling device is depicted in FIG. 5. The reflective mirror 111 is held by a mirror-mounting 113 that is mounted to a lens barrel (not shown). The cooling device comprises a radiative-cooling plate 115, a Peltier element 117, a cooling jacket 131, and cooling tube 151. The radiative-cooling plate 115 is positioned opposite a reverse side of the mirror 111, wherein an obverse side (upper side of the mirror in the figure) is the reflective face of the mirror. Thus, the radiative-cooling plate 115 receives radiated heat from the mirror 111. The Peltier element 117 is mounted in contact with a reverse face of the radiative-cooling plate 115, wherein the obverse face of the radiative-cooling plate is situated opposite the reverse side of the mirror 111. The Peltier element 117 (Peltier module) is a cooling element that exploits the thermoelectric effect. Whenever an electrical current is applied to the Peltier element 117, one face thereof absorbs heat, and the other face thereof emits heat. A cooling jacket 131 is mounted on a reverse face of the Peltier element 117 (called the heat-dissipating face), wherein the obverse face of the Peltier element is in contact with the reverse face of the radiative-cooling plate 115 (called the heat-absorbing face). As the electrical current passes through the Peltier element 117, heat is transferred from its heat-absorbing face to its heat-dissipating face. A temperature sensor (not shown) may be mounted on the heat-absorbing face or on the radiative-cooling plate 1115, and used for controlling transfer of heat, in a feedback-control manner, by controlling the current supplied to the Peltier element 117 according to the output from the temperature sensor. The heat transferred to the heat-dissipating face is transferred to a coolant medium passing through a coolant tube 151 in the cooling jacket 131. The coolant medium transfers the heat to outside the lens barrel.

In the conventional cooling device summarized above, the cooling jacket 131 is positioned proximally to the reflective mirror 111. Hence, the coolant tube 151 must be situated proximally to the mirror 111. Since the reflective mirror 111 is situated substantially in the center (viewed in transverse section) of the lens barrel, the coolant tube 151 also must be situated substantially in the center of the lens barrel. At the same time, the coolant tube 151 must be configured so as not to obstruct other mirrors or block the optical path of light passing through the optical system. To meet these criteria, configuring the coolant tube 151 with multiple bends is unavoidable; consequently, conventional cooling devices have the following problems. First, since the coolant tube must extend substantially to the center (in transverse section) of the lens barrel, there is a considerable risk of a coolant leak from the coolant tube, with consequent risk of substantial damage to the optical system. Also, maintenance of the cooling device is difficult. Second, as noted, the coolant tube inevitably has multiple bends that pose a significant risk of undesirable vibrations occurring in the coolant tube. These vibrations are readily transmitted to the lens barrel and other components, and can adversely affect performance of the optical system. Third, extension of the coolant tube to the center of the lens barrel necessitates that the tube be long, which reduces cooling performance.

In view of the above, there is a need for a mirror-cooling device that poses a reduced risk of liquid-coolant leaks, that poses a reduced risk of damage to the optical system in the event of a coolant leak from the coolant tube, that is easy to maintain, that minimizes coolant-tube vibrations and their deleterious effects on the optical system, and that provides satisfactory cooling performance.

### SUMMARY

Cooling devices as disclosed herein are operable to cool an optical element in an exposure apparatus. An embodiment of such a device comprises a cooling element that is situated proximally to the optical element. The device includes a heat-conduction member installed on the heat-dissipating side of the cooling element. The heat-conduction member extends in the exposure apparatus away from the optical element. The extended portion of the heat-conduction member is cooled, e.g., by contact with a coolant tube that is conducting a stream of coolant liquid. Thus, there is no need to position a coolant tube up to or proximal to the optical element. Also, the number of bends in the coolant tube is reduced, and the length of the coolant tube(s) can be reduced. By keeping the coolant tube(s) away from the optical elements, the probability of damage to the optical elements is substantially reduced in the event of a coolant leak. Also, maintenance of the coolant tubes is simplified. Further, by reducing the number of bends in the coolant tube, the propensity of the coolant tube to vibrate is substantially reduced, thereby reducing the effect of vibrations on the optical system. By reducing the length of the coolant tube, good cooling performance is maintained.

One embodiment of a cooling device is characterized in that the extended portion of the heat-conduction member is cooled at a peripheral region on the inside of a lens barrel containing one or more optical elements including a respective cooling device. The lens barrel is a portion of an optical system of an exposure apparatus, for example. By locating the coolant tube in a peripheral location inside the lens barrel relative to the optical element(s) inside the lens barrel, bends in the coolant tube are minimized or eliminated entirely, and the coolant tube can be shortened. Other benefits are as noted above, such as reduced leaks, reduced probability of leak damage to components in the lens barrel, reduced vibration, and simplified maintenance.

Another embodiment of a cooling device is characterized in that the extended portion of the heat-conduction member is cooled at a peripheral region on the outside of a lens barrel containing one or more optical elements including a respective cooling device. By locating the coolant tube in a peripheral location outside the lens barrel relative to the optical element(s) inside the lens barrel, bends in the coolant tube are minimized or eliminated entirely, and the coolant tube can be shortened. Other benefits are as noted above, such as reduced leaks, reduced probability of leak damage to components in the lens barrel, reduced vibration, and simplified maintenance.

Another embodiment of a cooling device is characterized in further comprising a heat-insulating cover that covers the heat-conduction member. This embodiment provides reduced radiative propagation of heat from the heat-conduction member to other optical elements and components in the lens barrel. The heat-insulating cover can be an integral member, which allows the heat-insulating cover to be easily installed, and increases the heat-conduction efficiency of the heat-conduction member. The heat-insulating cover can be formed of any of various thermally conductive metals and alloys, such as aluminum, tungsten, molybdenum, or zinc, to provide the heat-insulating cover with high heat-conduction efficiency. The surface of the heat-insulating cover desirably is polished to lower its thermal emissivity and reduce thermal radiation from the surface of the heat-insulating cover.

In yet another embodiment the heat-conduction member is an integral member, which allows the member to be easily installed and to exhibit high heat-conduction efficiency. Desirably, the heat-conduction member is made of a metal such as, but not limited to, aluminum, tungsten, molybdenum, or zinc, or alloys thereof to provide high heat-conduction efficiency. The surface of the heat-conduction member desirably is polished to lower its thermal emissivity, thereby reducing radiative heat propagation from the surface of the heat-conduction member. The heat-conduction member can be or can include, for example, at least one heat-pipe.

An embodiment of an exposure apparatus comprises at least one optical element that includes a cooling device as disclosed herein. Such an exposure apparatus exhibits all the advantages listed above, including minimal coolant-leak probability, minimal coolant-leak damage, simplified maintenance, reduced vibration, and good cooling performance. Desirably, the exposure apparatus (or optical system thereof) includes multiple reflective mirrors, as exemplary optical elements, each comprising a cooling device as disclosed herein. The respective heat-conduction members of the cooling devices are configured to extend to the same position (as viewed in a transverse section) in the lens barrel in which the optical elements are mounted. This results in fewer to no bends in coolant tubes used for cooling the heat-conduction members.

Thus, according to the invention, cooling devices, optical elements with cooling devices, optical systems including such optical elements, and exposure apparatus including such optical systems are provided that exhibit less problems with liquid coolants and coolant tubes, simplified maintenance, reduced vibration, and good cooling performance.

### BRIEF DESCRIPTION OF THE DRAWINGS

FIG. 1 is a schematic elevational view of a reflective mirror comprising an embodiment of a cooling device.

FIG. 2 is a schematic elevational view of an embodiment of a lens barrel for an optical system of an exposure apparatus, wherein the lens barrel comprises multiple reflective mirrors such as shown in FIG. 1.

FIG. 3 is a schematic elevational view of another embodiment of a lens barrel for an optical system of an exposure apparatus, wherein the lens barrel comprises multiple reflective mirrors such as shown in FIG. 1 and the cooling devices conduct heat outside the lens barrel.

FIG. 4 is a schematic elevational view of a reflective mirror comprising another embodiment of a cooling device.

FIG. 5 is a schematic elevational view of a reflective mirror comprising a conventional cooling device.

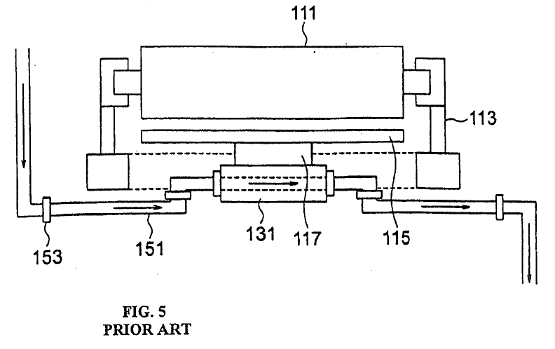

FIG. 6 is an optical diagram of a conventional projection-optical system as used in an EUV exposure apparatus.

FIG. 7 is a block diagram of a conventional exposure apparatus using EUV light.

FIG. 8 is a schematic elevational section of a portion of a reflective reticle used in an exposure apparatus comprising optical elements as disclosed herein.

FIG. 9 is a flow-chart of an exemplary microelectronic-device fabrication method in which systems and methods according to the invention can be applied readily.

FIG. 10 is a flow-chart of typical steps performed in microlithography, which is a principal step in the wafer-processing step shown in FIG. 9.

### DETAILED DESCRIPTION

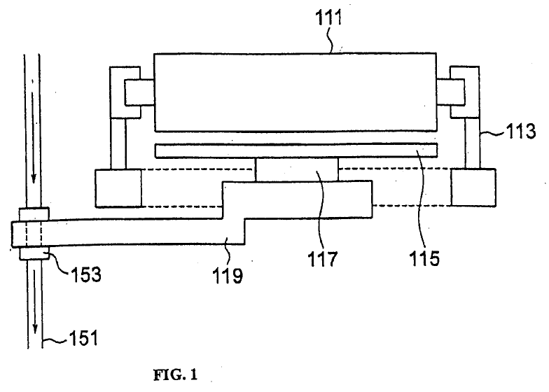

A first embodiment of a cooling device for a reflective mirror is shown in FIG. 1. A reflective mirror 111 is held by a mirror mounting 1113, and the mirror mounting is mounted to and held by a lens barrel (not shown). The cooling device comprises a radiative-cooling plate 115, a Peltier element 117, a heat-conduction member 119, and a coolant tube 151. The radiative-cooling plate 115 is situated opposite a reverse side of the mirror 111, wherein the obverse face (facing upward in the figure) of the mirror is the reflective surface of the mirror. Thus, the radiative-cooling plate 115 receives radiant heat from the reflective mirror 111. The Peltier element 117 (Peltier module) is in contact with a reverse face (downward-facing in the figure) of the radiative-cooling plate 115, wherein the obverse face of the radiative-cooling plate 115 faces the reverse face of the mirror 111. The heat-conduction member 119 is mounted on the reverse face (called the heat-dissipating face) of the Peltier element 1117, wherein the obverse face (called the heat-absorbing face) of the Peltier element is in contact with the reverse face of the radiative-cooling plate 115. The heat-absorbing face of the Peltier element 117 receives radiated heat from the reflecting mirror 111.

The heat-conduction member 119 extends to a peripheral region inside the lens barrel or alternatively to outside the lens barrel. Desirably, the heat-conduction member 119 is formed as an integral member from a metal to provide ease of installation and efficient heat conduction. Depending upon circumstances, two or more such members may be linked together. Even when two or more members are used, installation is easier than connecting tubes for liquid coolant. Although the heat-conduction member 119 is mounted within the lens barrel, the danger of liquid leaks associated with use of a coolant tube is eliminated. The heat-conduction member 119 also requires little to no maintenance, and has an extremely small risk (compared to a coolant tube) of conducting or imparting vibrations to the lens barrel. Consequently, the optical system in the lens barrel is less affected by vibrations.

The coolant tube 151 is situated well away from the respective optical element 111, thereby minimizing risk of damage to the element by a coolant leak, and is situated to provide easy access, thereby providing easy maintenance. Also, the coolant tube 151 in this embodiment is substantially shorter than in conventional systems, which improves cooling performance.

As the material of the heat-conduction member 1119, a metal with high thermal conductivity, in particular aluminum or an alloy thereof, is desirable. Other materials that can be used include simple metals having a thermal conductivity of 100 W/(m·K) or higher. These metals include silver, copper, gold, beryllium, tungsten, magnesium, rhodium, silicon, iridium, molybdenum, sodium, zinc, ruthenium, and potassium. Of these alternative metals, tungsten, molybdenum, and zinc are desired from the standpoint of low cost, low toxicity, stability, and other properties.

As the heat-conduction member 119 extends within the lens barrel to the optical element 111, it is desirable to reduce radiative heat propagation from the surface of the member 119 to other surfaces by polishing the surface.

The heat-conduction member 119 may comprise one or more heat pipes. A heat pipe, for example, comprises a sealed vessel that contains a small amount of a volatile fluid (“working fluid”) and that has a capillary-tube structure in its inner walls. One portion (heated portion) of the heat pipe is situated in proximity to the optical element, and the other portion (low-temperature portion) is situated at the peripheral region of the lens barrel or outside the lens barrel. In the heated portion the working fluid is caused to evaporate, and the latent heat of vaporization is absorbed. The vapor of the working fluid moves to the low-temperature portion, condenses in the low-temperature portion, and releases the latent heat of vaporization. The condensed working fluid is recirculated to the heated portion by means of a capillary effect exhibited by the capillary-tube structure. In this way, heat is moved from the heated portion to the low-temperature portion of the heat pipe. When the heat-conduction member 119 comprises one or more heat pipes, the possibility of liquid leaks and of vibrations is reduced compared to a case in which a cooling tube is installed in proximity to the optical element. Further, the above-described metal or other heat-conduction member may be combined with heat pipe(s).

As an electrical current is passed through the Peltier element 117, heat is transferred from its heat-absorbing face to its heat-dissipating face. A temperature sensor (not shown) is installed either on the heat-absorbing face or on the radiative-cooling plate 115. The current passed through the Peltier element 117 is controlled by the output of the temperature sensor, to control heat-transfer. Heat transferred to the heat-dissipating face is conducted to the heat-conduction member 119. The heat-conduction member 119 conducts the heat to a peripheral region within the lens barrel or to a region outside the lens barrel.

The extended portion of the heat-conduction member 119 is attached to the coolant tube 151 by a coupling 153. Thus, the heat-conduction member 119 is cooled by the coolant flowing in the coolant tube 151.

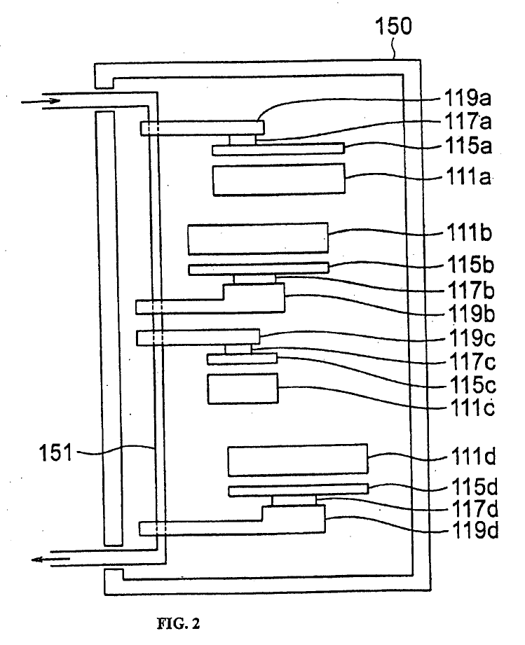

FIG. 2 depicts an embodiment of a lens barrel 150 of an exposure apparatus. The lens barrel 150 contains a plurality of reflective mirrors such as the mirror shown in FIG. 1. In FIG. 2, for simplicity, four reflective mirrors 111a-111d are shown. Each reflective mirror 111a, 111b, 111c, 111d is provided with a respective cooling device. Each cooling device comprises a respective radiative-cooling plate 115a, 115b, 115c, 115d, a respective Peltier element 117a, 117b, 117c, 117d, and a respective heat-conduction member 119a, 119b, 119c, 119d. The heat-conduction members 119a-119d extend to a peripheral region inside the lens barrel 150. Although not shown, the heat-conduction members 119a, 119b, 119c, 119d may be configured so as to be held by the lens barrel 150. Attachment of a heat-conduction member to the lens barrel 150 desirably is performed using a stay having small cross-sectional area to reduce heat exchange between the heat-conduction member and the lens barrel.

In FIG. 2, the heat-conduction members 119a, 119b, 119c, 119d extend to substantially the same position (in a transverse section) of the lens barrel. Thus, the number of bends in the coolant tube 151 can be minimized. Also, within the lens barrel, the coolant tube can extend straight in the vertical direction. Since the coolant tube 151 is located in a peripheral region within the lens barrel 150, any damage resulting from a coolant leak is reduced compared to a conventional system. Also, coolant-tube maintenance is simplified. By configuring the coolant tube 151 vertically straight, with few bends, the probability of vibrations of the coolant tube is reduced, and the affect of any such vibrations on the optical system is reduced. Also, configuring the coolant tube 151 straight as shown allows the length of the tube to be reduced, thereby maintaining good cooling performance.

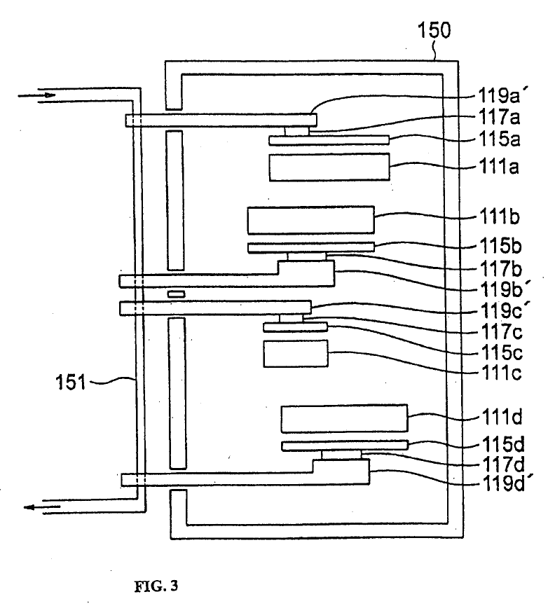

FIG. 3 shows another embodiment of a lens barrel 150 of an exposure apparatus. The lens barrel 150 comprises a plurality of reflective mirrors 111a-111d similar to the mirror shown in FIG. 1. In FIG. 3, for simplicity, four reflective mirrors 111a, 111b, 111c, 111d are shown. The mirrors are provided with respective cooling devices, each comprising a respective radiative-cooling plate 115a, 115b, 115c, 115d, a respective Peltier element 117a, 117b, 117c, 117d, and a respective heat-conduction member 119a′, 119b′, 119c′, 119d′. The heat-conduction members 119a′, 119b′, 119c′, 119d′ in this embodiment extend to the outside the lens barrel 150 rather than terminate inside the lens barrel. The heat-conduction members 119a′, 119b′, 119c′, 119d′ extend to the same region (in a transverse section of the lens barrel 150) in the exposure apparatus. Thus, the number of bends in the coolant tube 151 is reduced. Outside the lens barrel 150, the coolant tube is straight in the vertical direction.

Since the coolant tube 151 is situated outside the lens barrel 150, possible damage to components in the lens barrel from coolant leaks is reduced, and maintenance is simplified. Since the coolant tube 151 is straight, bends are eliminated or reduced, with corresponding reduction in incidence and effects of vibrations of the coolant tube 151 on the optical system. Also, by making the coolant tube 151 straight, it length is reduced, thereby maintaining good cooling performance.

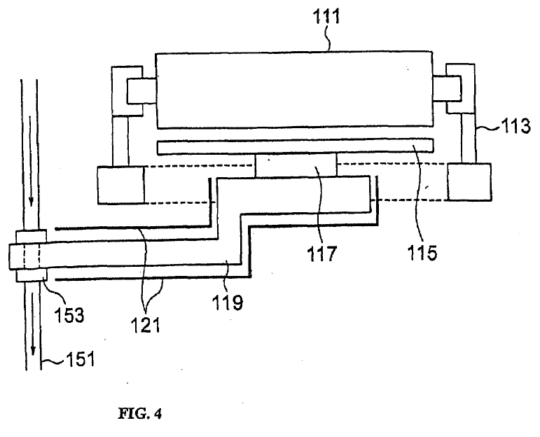

FIG. 4 depicts a reflective mirror comprising an embodiment of the cooling device. The mirror 111 is held by a mirror mounting 113, and the mounting is attached to a lens barrel (not shown). The cooling device comprises a radiative-cooling plate 115, a Peltier element 117, a heat-conduction member 119, and a coolant tube 151. The radiative-cooling plate 115 is situated opposite the reverse face of the reflective mirror 111, wherein the obverse face of the mirror is the reflective face. The radiative-cooling plate receives radiant heat from the reflective mirror 111. The Peltier element 117 is mounted in contact with the reverse face of the radiative-cooling plate 115, wherein the obverse face of the plate is opposite the reverse face of the mirror 111. The heat-conduction member 119 is mounted on the reverse face (called the heat-dissipating face) of the Peltier element 117, wherein the obverse face (called the heat-absorbing face) of the Peltier element 117 is mounted in contact with the reverse face of the radiative-cooling plate 115. The heat-absorbing face of the Peltier element 117 may receive radiant heat directly from the reflective mirror 111.

The heat-conduction member 119 extends to a peripheral region inside the lens barrel or outside the lens barrel. The structure, materials, and the like of the heat-conduction member 119 are as described with respect to the embodiment shown in FIG. 1. In this embodiment a heat-insulating cover 121 substantially surrounds the heat-conduction member 119. The heat-insulating cover 121 extends to surround the heat-conduction member 119 inside the lens barrel, and is held by the lens barrel. Similarly to the heat-conduction member 119, the heat-insulating cover 121 may be cooled at the peripheral region of the lens barrel.

From the standpoint of ease of installation and heat-conduction efficiency, the heat-insulating cover 121 desirably is formed integrally from a metal. Depending on circumstances, two or more members may be linked together to form the heat-insulating cover. The heat-insulating cover 121 desirably is made of a metal having a high thermal conductivity. A particularly advantageous metal in this regard is aluminum or an alloy thereof. Other suitable metals include, but are not limited to, tungsten, molybdenum, and zinc. As the heat-insulating cover 121 extends within the lens barrel, to reduce radiative heat propagation from the surface of the heat-insulating cover to other components in the lens barrel, the surface of the cover desirably is polished.

As an electrical current is passed through the Peltier element, heat is transferred from its heat-absorbing face to its heat-dissipating face. A temperature sensor (not shown) may be mounted on the heat-absorbing face or on the radiative-cooling plate 115. The temperature sensor can be used for feedback-control of the current delivered to the Peltier element according to the output from the temperature sensor, thereby controlling heat transfer. The heat transferred to the heat-dissipating face is conducted to the heat-conduction member 119 and transferred to the peripheral region within the lens barrel or to a region outside the lens barrel.

The extended portion of the heat-conduction member 119 is attached to the coolant tube 151 by a coupling 153, and thus is cooled by the coolant tube 151. Within the lens barrel, since the heat-conduction member 119 is covered by the heat-insulating cover 121, radiative propagation of heat from the heat-conduction member 119 to other reflective mirrors or other components in the lens barrel is prevented.

In the foregoing, features of embodiments of cooling devices, as used with reflective mirrors in a projection-optical system of an exposure apparatus, have been described. Alternatively or in addition, the subject cooling device can be used with a reflective mirror in an illumination-optical system of an exposure apparatus, and/or with another optical element in an exposure apparatus for which temperature regulation is necessary.

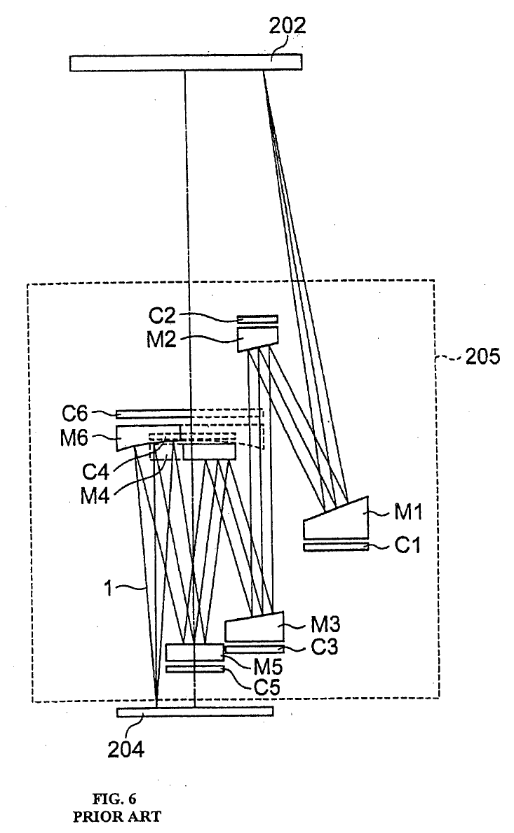

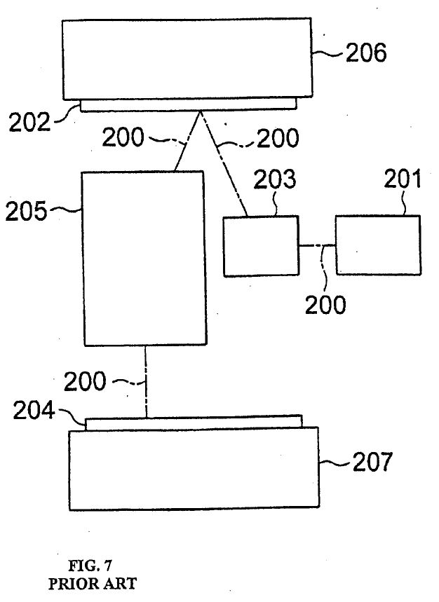

The configuration of an embodiment of an exposure apparatus according to the invention is similar in many ways to the exposure apparatus depicted in FIG. 7. A projection-optical system of an exposure apparatus of this invention is similar in many ways to the projection-optical system shown in FIG. 6, except that at least of the cooling devices C1-C6 comprises a heat-conduction member as described above.

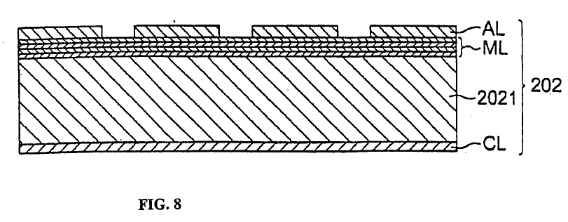

FIG. 8 depicts and embodiment of a reticle 202 used in an exposure apparatus according to the invention. A multilayer film ML, to make the reticle reflective to incident EUV light, is situated on the upper surface of a substrate 2021 made of low-expansion glass. A patterning layer (e.g., an absorptive layer AL) is formed on the multilayer film ML. The absorptive layer AL is patterned according to a desired circuit pattern or the like to be exposed; features of the circuit pattern are defined by the presence or absence of the absorptive layer AL. A conductive film CL is formed on the lower surface of the substrate 2021, i.e., on the surface opposite the upper surface. The lower surface is the chucked surface of the substrate 2021. The conductive film CL allows the reticle 202, although made from a low-expansion glass substrate to be used with an electrostatic chuck. The multilayer film ML, absorptive layer AL, and conductive film CL are deposited by respective sputtering steps.

The selectable range of the specific material from which the conductive film CL can be made is broad, and includes metals in general (e.g., Cr, Ni, Ta, and other metals and alloys), semiconductors, and the like.

The specific multilayer film ML for use in reflecting incident EUV light depends upon the particular wavelength of EUV light. When, for example, a wavelength of 13-14 nm is used, the multilayer film ML desirably comprises 40 to 50 pairs of layers of Mo (molybdenum) and Si (silicon). The layers desirably alternate with a period equal to approximately half the wavelength, and are formed in a superposed stacked configuration. Using such a multilayer film ML, a reflectivity of approximately 70% is obtained in the normal direction.

In a large-NA (numerical aperture) optical system usable with EUV light, the range of incidence angles at the reticle is extremely large. For an ordinary equal-period multilayer film ML, the reflectivity over the range of incidence angles is broadly distributed between approximately 50% and 74%. The reticle can be formed such that the multilayer film ML has certain regions in which the respective periods are not equal and other regions in which the periods are equal, so as to prevent the reflectivity from the reticle from assuming a distribution, even over a broad range of incidence angle. I.e., with such a reticle, the reflectivity distribution is substantially “flat.” Here, an equal-period multilayer film is a multilayer film in which, for example, Mo (molybdenum) layers of a fixed thickness and Si (silicon) layers of a fixed thickness are stacked repeatedly. In an unequal-period multilayer film of Mo and Si, for example, multiple Mo layers of different thicknesses and multiple Si layers of different thicknesses are stacked.

In the multilayer film ML of the reticle 202, layer thicknesses and the like are optimized according to the incidence wavelength, incidence angle, range of incidence angle, and other optical-system conditions in the exposure apparatus. If a reticle is used that does not conform to the optical-system conditions of the exposure apparatus, the projection-optical system of the exposure apparatus cannot exhibit adequate imaging performance (such as proper focus). By encoding multilayer-film design information for the reticle on a barcode or the like imprinted on the reticle, upon mounting the reticle in the apparatus, the apparatus can “read” the information for the reticle, and provide data or control functions according to whether the reticle conforms to the exposure apparatus.

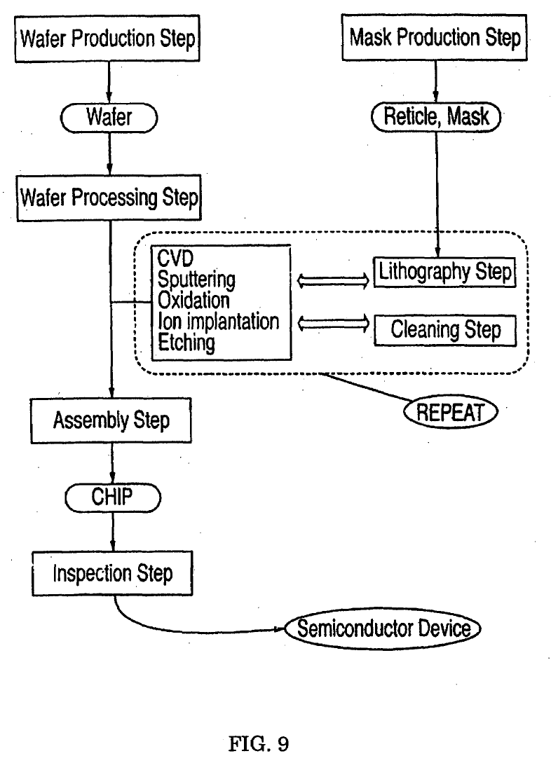

FIG. 9 is a flow-chart of an exemplary microelectronic-device fabrication method in which systems and methods according to the invention can be applied readily. The fabrication method generally comprises the main steps of wafer production (wafer manufacturing or preparation), reticle (mask) production or preparation, wafer processing, device (chip) assembly (including dicing of chips and rendering the chips operational), and device (chip) inspection. Each step usually comprises several sub-steps.

Among the main steps, wafer processing is key to achieving the smallest feature sizes (critical dimensions) and best inter-layer registration. In the wafer-processing step, multiple circuit patterns are layered successively atop one another on the wafer, forming multiple chips destined to be memory chips or main processing units (MPUs), for example. The formation of each layer typically involves multiple sub-steps. Usually, many operative microelectronic devices are produced on each wafer.

Typical wafer-processing steps include: (1) thin-film formation (by, e.g., sputtering or CVD) involving formation of a dielectric layer for electrical insulation or a metal layer for connecting wires or electrodes; (2) oxidation step to oxidize the substrate or the thin-film layer previously formed; (3) microlithography to form a resist pattern for selective processing of the thin film or the substrate itself; (4) etching or analogous step (e.g., dry etching) to etch the thin film or substrate according to the resist pattern; (5) doping as required to implant ions or impurities into the thin film or substrate according to the resist pattern; (6) resist stripping to remove the remaining resist from the wafer; and (7) wafer inspection. Wafer processing is repeated as required (typically many times) to fabricate the desired microelectronic devices on the wafer.

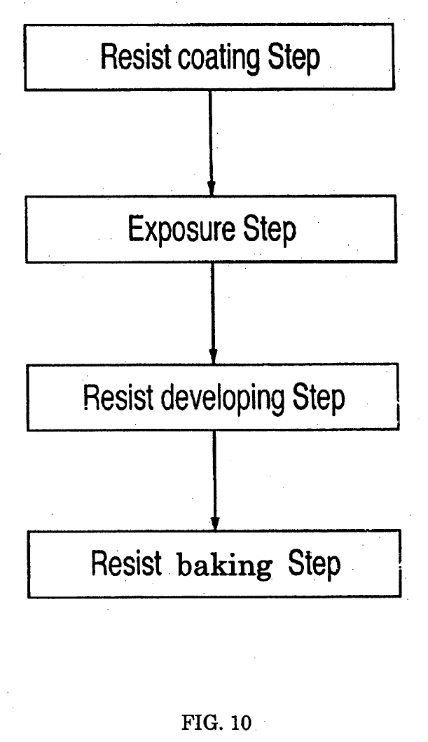

FIG. 10 provides a flow-chart of typical steps performed in microlithography, which is a principal step in the wafer-processing step shown in FIG. 9. The microlithography step typically includes: (1) resist-application step, wherein a suitable resist is coated on the wafer substrate (which can include a circuit element formed in a previous wafer-processing step); (2) exposure step, to expose the resist with the desired pattern by microlithography; (3) development step, to develop the exposed resist to produce the imprinted image; and (4) optional resist-annealing step, to enhance the durability of and stabilize the resist pattern.

The process steps summarized above are all well-known and are not described further herein.

As disclosed herein, by providing a cooling device in which the heat-conduction member is in contact with a Peltier element, the cooling device has substantially reduced probability of damage to neighboring components due to leaks of liquid coolant from the coolant tube. Thus, maintenance is simplified, vibrations of the coolant tube are reduced, effects of such vibrations on the optical system are reduced, and good cooling performance is maintained.

What is claimed is:

1. A device for cooling an optical element in an optical system, the device comprising:
a heat-transfer element situated in proximity to the optical element, the cooling element including a heat-absorbing portion and a heat-dissipating portion, the heat-absorbing portion being situated relative to the optical element to absorb heat from the optical element; and
a heat-conduction member coupled to the heat-dissipating portion of the cooling element to conduct heat from the heat-dissipating portion, the heat-conduction member including an extended portion that extends away from the optical element in the optical system; wherein
the extended portion of the heat-conduction member is cooled.

2. The device of claim 1, wherein:
the optical element is situated in a lens barrel of the optical system;
the lens barrel includes a peripheral region; and
the extended portion of the heat-conduction member is cooled at the peripheral region.

3. The device of claim 1, wherein:
the optical element is situated in a lens barrel of the optical system; and
the extended portion of the heat-conduction member is cooled outside the lens barrel.

4. The device of claim 1, wherein the heat-conduction member comprises a heat-insulating cover.

5. The device of claim 4, wherein the heat-insulating cover is an integral member.

6. The device of claim 4, wherein the heat-insulating cover is formed from a metal selected from the group consisting of aluminum, tungsten, molybdenum, and zinc, and alloys and mixtures thereof.

7. The device of claim 4, wherein the heat-insulating cover comprises a polished surface.

8. The device of claim 1, wherein the heat-conduction member is an integral member.

9. The device of claim 1, wherein the heat-conduction member is formed from a metal selected from the group consisting of aluminum, silver, copper, gold, beryllium, tungsten, magnesium, rhodium, silicon, iridium, molybdenum, sodium, zinc, ruthenium, zinc, and potassium, and alloys and mixtures thereof.

10. The device of claim 9, wherein the heat-conduction member is formed from a metal selected from the group consisting of aluminum, tungsten, molybdenum, and zinc, and alloys and mixtures thereof.

11. The device of claim 1, wherein the heat-conduction member comprises a polished surface having reduced emissivity compared to a non-polished surface.

12. The device of claim 1, wherein the heat-conduction member comprises at least one heat-pipe.

13. The device of claim 1, wherein:
the heat-dissipating portion comprises a Peltier element comprising a heat-absorbing face and a heat-dissipating face;
the heat-absorbing face is situated relative to the optical element sufficiently to draw heat from the optical element; and
the heat-dissipating face is in thermal contact with the heat-conduction member.

14. The device of claim 1, wherein the heat-absorbing portion comprises a radiative-cooling plate situated relative to the optical element sufficiently to draw heat from the optical element.

15. The device of claim 14, wherein:
the heat-dissipating portion comprises a Peltier element comprising a heat-absorbing face and a heat-dissipating face;
the heat-absorbing face is in thermal contact with the radiative-cooling plate; and
the heat-dissipating face is in thermal contact with the heat-conduction member.

16. The device of claim 1, wherein the extended portion of the heat-conduction member is cooled by thermal contact with a coolant fluid flowing in a coolant tube.

17. The device of claim 16, wherein:
the optical element is situated in a lens barrel of the exposure apparatus; and
the coolant tube is situated in a peripheral region of the lens barrel.

18. The device of claim 17, wherein the peripheral region is inside the lens barrel.

19. The device of claim 17, wherein the peripheral region is outside the lens barrel.

20. An optical device, comprising:
an optical element; and
a cooling device for cooling the optical element, the cooling device comprising (a) a heat-transfer element situated in proximity to the optical element, the cooling element including a heat-absorbing portion and a heat-dissipating portion, the heat-absorbing portion being situated relative to the optical element to absorb heat from the optical element, and (b) a heat-conduction member coupled to the heat-dissipating portion of the cooling element to conduct heat from the heat-dissipating portion, the heat-conduction member including an extended portion that extends away from the optical element in the exposure apparatus, wherein the extended portion of the heat-conduction member is cooled.

21. The optical device of claim 20, wherein the optical element is a mirror.

22. The optical device of claim 20, further comprising a lens barrel containing the optical element, wherein the extended portion of the heat-conduction member extends to a peripheral region of the lens barrel and is cooled in the peripheral region.

23. An optical system, comprising at least one optical device as recited in claim 20.

24. An exposure apparatus, comprising at least one optical device as recited in claim 20.

25. An exposure apparatus, comprising:
a lens barrel having a peripheral region;
multiple reflective optical elements mounted in the lens barrel; and
at least one of the reflective optical elements comprising a cooling device for cooling the optical element, the cooling device comprising (a) a heat-transfer element situated in proximity to the optical element, the cooling element including a heat-absorbing portion and a heat-dissipating portion, the heat-absorbing portion being situated relative to the optical element to absorb heat from the optical element, and (b) a heat-conduction member coupled to the heat-dissipating portion of the cooling element to conduct heat from the heat-dissipating portion, the heat-conduction member including an extended portion that extends away from the optical element in the exposure apparatus, wherein the extended portion of the heat-conduction member is cooled.

26. The exposure apparatus of claim 25, wherein:
multiple reflective optical elements in the lens barrel comprise respective said cooling devices; and
the extended portions of the respective heat-conduction members extend to the peripheral region of the lens barrel for cooling at a same position in a lateral cross-section of the lens barrel.

27. The exposure apparatus of claim 26, wherein the extended portions are cooled by being in thermal contact with a coolant fluid passing through a coolant tube extending in the lens barrel at the same position in the lateral cross-section.

28. The exposure apparatus of claim 26, wherein the peripheral region where the extended portions are cooled is located inside the lens barrel.

29. The exposure apparatus of claim 26, wherein the peripheral region where the extended portions are cooled is located outside the lens barrel.

30. The exposure apparatus of claim 25, wherein the extended portions comprise respective one or more heat pipes.

31. A microelectronic-device manufacturing process, comprising:
(a) preparing a substrate;
(b) processing the substrate; and
(c) assembling microelectronic devices formed on the substrate during steps (a) and (b), wherein step (b) comprises the steps of (i) applying a resist to the substrate; (ii) exposing the resist; and (iii) developing the resist; and step (ii) comprises providing an exposure apparatus as recited in claim 24 and using the exposure apparatus to expose the resist with the pattern defined in the reticle.

32. A microelectronic-device manufacturing process, comprising:
(a) preparing a substrate;
(b) processing the substrate; and
(c) assembling microelectronic devices formed on the substrate during steps (a) and (b), wherein step (b) comprises the steps of (i) applying a resist to the substrate; (ii) exposing the resist; and (iii) developing the resist; and step (ii) comprises providing an exposure apparatus as recited in claim 25 and using the exposure apparatus to expose the resist with the pattern defined in the reticle.

33. A microelectronic-device manufacturing process, comprising:
(a) preparing a substrate;
(b) processing the substrate; and
(c) assembling microelectronic devices formed on the substrate during steps (a) and (b), wherein step (b) comprises the steps of (i) applying a resist to the substrate; (ii) exposing the resist; and (iii) developing the resist; and step (ii) comprises providing an exposure apparatus as recited in claim 26 and using the exposure apparatus to expose the resist with the pattern defined in the reticle.
